(19) United States
(12) Patent Application Publication
(10) Pub. No.: US 2023/0187296 A1
(43) Pub. Date: Jun. 15, 2023

(54) DIE ATTACHMENT METHOD FOR SEMICONDUCTOR DEVICES AND CORRESPONDING SEMICONDUCTOR DEVICE

(71) Applicant: STMICROELECTRONICS S.r.l., Agrate Brianza (IT)

(72) Inventors: Guendalina CATALANO, Siracusa (IT); Nicoletta MODARELLI, Milano (IT)

(73) Assignee: STMICROELECTRONICS S.r.l., Agrate Brianza (IT)

(21) Appl. No.: 18/062,479

(22) Filed: Dec. 6, 2022

(30) Foreign Application Priority Data
Dec. 10, 2021 (IT) 102021000031007

(51) Int. Cl. H01L 23/31; H01L 23/495; H01L 21/48

(52) U.S. Cl. CPC H01L 23/3142; H01L 23/3114; H01L 23/49513; H01L 21/4821

(57) ABSTRACT

The present disclosure is directed to a method of manufacturing semiconductor devices that includes providing a substrate such as a leadframe having a non-etched adhesion promoter, NEAP layer over the die mounting surface and attaching thereon a semiconductor die having an attachment surface including a first and a second die areas that are wettable by electrically conductive solder material. The NEAP layer is selectively removed, e.g., via laser ablation, from the first substrate area and the second substrate area of the die mounting surface of the substrate. The first substrate area and the second substrate area of the substrate having complementary shapes with respect to the first and second die areas of the semiconductor die. Electrically conductive solder material is dispensed on the first and second substrate areas of the substrate. A semiconductor die is flipped onto the substrate with the first die area and the second die area aligned with the first substrate area and the second substrate area of the substrate having the solder material dispensed thereon. The electrically conductive solder material thus provides electrical coupling of: the first die area and the first substrate area, and the second die area and the second substrate area.

### BACKGROUND

### Technical Field

The description relates to manufacturing semiconductor devices and manufacturing integrated circuits (ICs).

### Description of the Related Art

Non-Etched Adhesion Promoter (NEAP) leadframe surface finish is now commonly used in manufacturing semiconductor devices. This is primarily in view of the excellent adhesion to the molding compound facilitated by a very thin oxide layer. For instance, such a thin oxide layer can be formed on a silver-plated leadframe with the NEAP product marketed under the trade designation “AgPrep” by Atotech Deutschland GmbH.

It is otherwise noted that NEAP finish can be hardly proposed for high-reliability packages where high thermal and electrical conductivity are desired features.

Indeed, a NEAP oxide layer may exhibit reduced compatibility with solder materials involving some sort of sintering (such as hybrid glue and sintering paste, for instance) or based on metal bonds (such as soft solder and solder paste, for instance), which results in reduced bonding strength between an integrated circuit chip and the leadframe.

### BRIEF SUMMARY

One or more embodiments of the present disclosure contribute in overcoming the drawbacks outlined in the foregoing while also providing an improved process for mounting semiconductor chips on a substrate, such as a NEAP-finished leadframe.

One or more embodiments relate to a method having the features set forth in the detailed description that follows. One or more embodiments relate to a corresponding semiconductor device (an integrated circuit, for instance).

The claims are an integral part of the technical teaching provided herein in respect of the embodiments.

One or more embodiments involve (selective) removal of the NEAP layer, via laser beam ablation, for instance, in order to restore wettability of the underlying material (copper, silver or various alloys, for instance) which facilitates soft-solder die attachment in combination with NEAP handling extended to flip-chip power Quad-Flat No-leads (QFN) die packages.

In various examples presented herein, ablated NEAP areas are used as a solder mask (for, e.g., hybrid glue) in order to define die-to-leadframe connection areas for a semiconductor chip such as a flip-chip power die.

In various examples presented herein, ablated NEAP areas match a wettable area in the die when flipped. This can provide electrical connection to the power die. For instance, a power transistor may have its drain and gate connected to a die pad with the source connection provided by a further clip.

In various examples presented herein, a device package and an associated manufacturing method may involve selective removal of NEAP to provide a sort of solder mask defining at least two electrically isolated die pad regions to provide two corresponding areas for the provision of die attach material; flip-chip mounting of a die can thus occur at the solder wettable regions thus formed.

### BRIEF DESCRIPTION OF THE SEVERAL VIEWS OF THE DRAWINGS

One or more embodiments will now be described, by way of example, with reference to the annexed figures, wherein:

FIGS. 1 to 9 are exemplary of various steps in manufacturing a semiconductor device according to embodiments of the present description; there, FIGS. 5 and 7 are cross-sectional views along line V-V in FIG. 4 and line VII-VII in FIG. 6, respectively,

FIG. 10 is exemplary of a substrate (leadframe) with Non-Etched Adhesion Promoter (NEAP) surface finish,

FIG. 11 is generally exemplary of applying laser beam ablation energy to a substrate with NEAP surface finish as exemplified in FIG. 10,

FIGS. 12A and 12B are exemplary of a first manner of applying laser beam ablation energy to a substrate with NEAP finish, and

FIGS. 13A and 13B are exemplary of another manner of applying laser beam ablation energy to a substrate with NEAP finish.

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION

In the ensuing description one or more specific details are illustrated, aimed at providing an in-depth understanding of examples of embodiments. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The references used herein are provided merely for convenience and hence do not define the extent of protection or the scope of the embodiments.

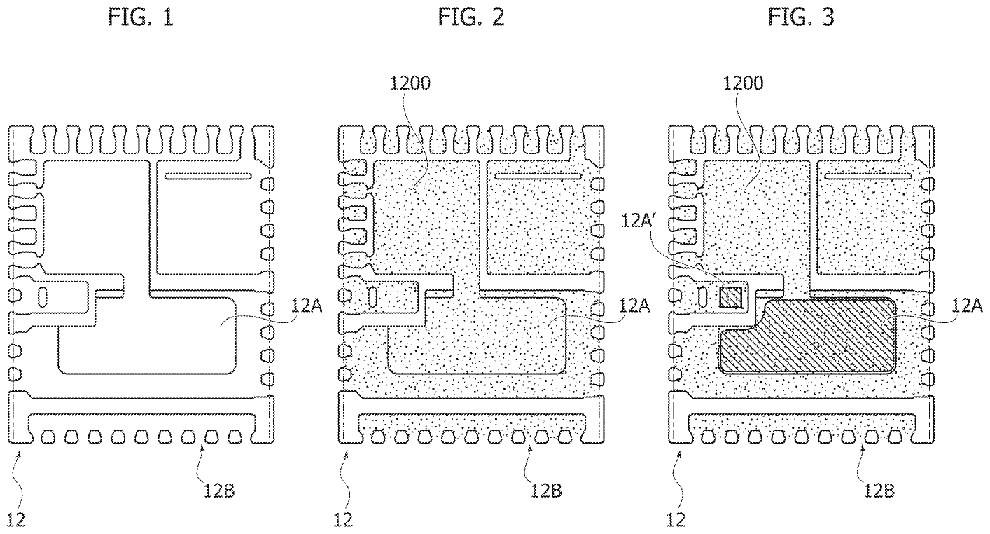

FIGS. 1 to 9 refer to manufacturing a semiconductor device according to examples of the present description.

A semiconductor device 10 as considered herein (see, e.g., the plan view of FIG. 9) may be a semiconductor device 10 in Quad-Flat No-leads (QFN) package.

Such a device 10 includes (along with other elements/features not visible in the figure for simplicity) a substrate such as a so-called leadframe 12 (of, e.g., copper, silver or various alloys) intended to include (mutually isolated) die pad areas 12A, 12A′ where a semiconductor chip or die 16 can be attached, e.g., via electrically conductive solder material 120 (see, e.g., FIGS. 6 and 7 discussed later).

In the following, mounting a single chip or die 16 on the substrate 12 will be discussed for simplicity; in various embodiments, plural chips or dice 16 can be mounted on the substrate (leadframe) 12.

The leadframe 12 also includes an array of electrically conductive leads 12B around the die pad(s) 12A, 12A′ and the semiconductor chip or die 16 (the terms chip and die are used herein as synonyms) attached thereon.

The designation “leadframe” (or “lead frame”) is currently used (see, for instance the USPC Consolidated Glossary of the United States Patent and Trademark Office) to indicate a metal frame that provides support (e.g., at a die pad such as 12A) for an integrated circuit chip or die 16 (these terms are used herein as synonyms) as well as electrical leads such as 12B to interconnect the integrated circuit in the die or chip to other electrical components or contacts.

Leadframes are conventionally created using technologies such as a photo-etching technology. With this technology, metal material (e.g., copper, silver or various alloys) in the form of a foil or tape is etched on the top and bottom sides to create various pads and leads.

A mass 18 of package molding compound—an epoxy resin, for instance—whose outline is illustrated in dashed lines in FIG. 9, can be molded onto the leadframe 12 to provide an isolating encapsulation for the chip or die 16.

It is noted that the indication “No-leads” referred to a QFN device 10 as depicted herein is not in contradiction with such a package comprising an array of leads such as 12B: in fact, the indication “No-leads” is related to the fact that a QFN package is substantially exempt from external (distal) tips of the leads in the leadframe 12 protruding from the encapsulation 18.

As illustrated, the device 10 comprises (at least) one semiconductor chip or die 16 mounted bridge-like between the first die pad 12A and the second die pad 12A′ in the leadframe 12. This may be via die attachment material 120.

A soft-solder attach material can be exemplary of such a die attachment material.

The designation “soft-solder” belongs to the current language in the area of semiconductor circuit manufacturing as a conventional designation for solders such as, for instance, tin-lead (Sn—Pb) solders that are commercially available with tin concentrations between 5% and 70% by weight. A composition of Pb 95%/Sn 5% or sometimes 1-2% Ag and Sn balance may be exemplary of such a soft-solder attach material.

As discussed, Non-Etched Adhesion Promoter (NEAP) leadframe surface finish is now used in manufacturing semiconductor devices in view of the excellent adhesion to the molding compound facilitated by a very thin oxide layer.

It is otherwise noted that NEAP finish can be hardly proposed for high-reliability packages where high thermal and electrical conductivity are desired features. Indeed, a NEAP oxide layer may exhibit reduced compatibility with materials involving some sort of sintering (such as hybrid glue and sintering paste, for instance) or based on metal bonds (such as soft solder and solder paste, for instance).

As discussed previously, while promoting good adhesion with the package compound (e.g., 18 in FIG. 9), a NEAP enhancing layer was found to adversely affect the attachment process of the semiconductor die or dice 16 onto the die pad or pads of the leadframe 12, via, e.g., hybrid glues.

Even without wishing to be bound to any specific theory in that respect, one may note, for instance, that in hybrid glues, hybrid die attach material—with high resin contents to exploit (also) chemical adhesion—has limited thermal and electrical performance.

Conversely, a reduced amount of resin and a high content of filler (e.g., silver particles) may result in a reduced adhesion to a NEAP leadframe. This is in contrast with standard glues, which may achieve good adhesion to a thin oxide layer thanks to the high amount of resin.

Also, the portion of the leadframe under the die pad area could be protected through masking during the process of forming the last oxide layer of NEAP. This would otherwise lead to a fairly expensive process, not flexible enough to adapt to variable die sizes and shapes.

Examples as considered herein address these issues along the same line of document US 2020/402895 A1 (assigned to the same assignee of the present application), where selectively removing a surface layer on a die pad before die attach is proposed.

FIGS. 1 to 9 are exemplary of various steps in manufacturing a semiconductor device such as the device 10.

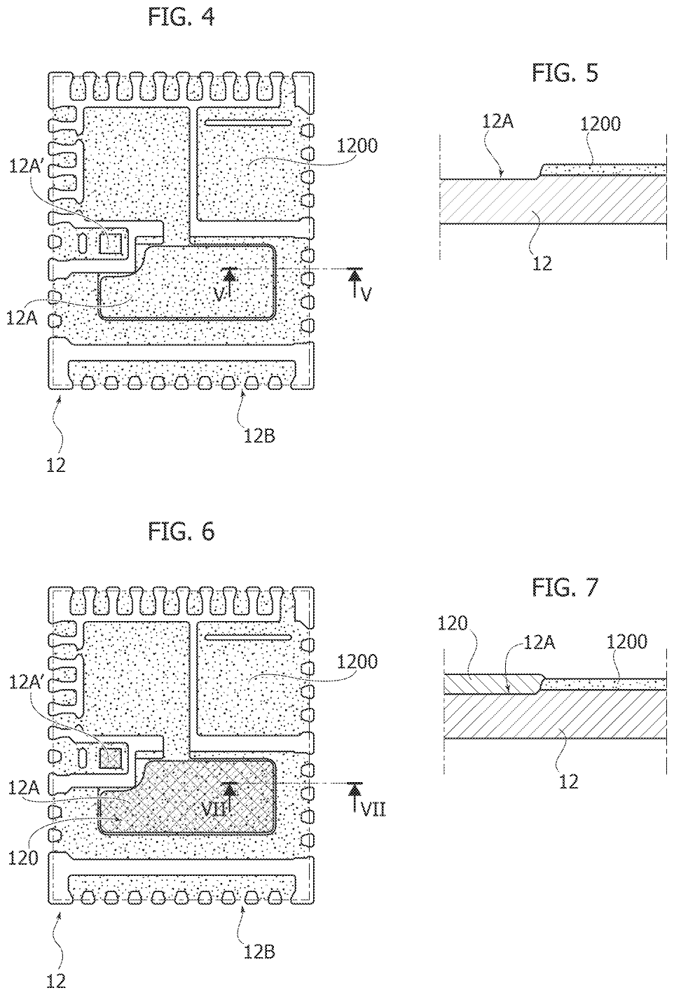

As noted, FIGS. 5 and 7 essentially correspond to cross-sectional views along lines V-V in FIG. 4 and VII-VII in FIG. 6, respectively, that further illustrate the results of the steps of FIGS. 4 and 6.

It will be otherwise appreciated that the sequence of steps of FIGS. 1 to 9 is merely exemplary.

In the first place, manufacturing a single device 10 is illustrated in FIGS. 1 to 9 for simplicity.

In fact, current production processes of semiconductor devices involve a chain or string of devices manufactured simultaneously to be finally separated into individual devices 10 via a “singulation” step (e.g., cutting the chain or string between adjacent devices via a blade).

Also:
one or more steps illustrated in FIGS. 1 to 9 can be omitted, performed in a different manner (with other tools, for instance) and/or replaced by other steps;
additional steps may be added;
one or more steps can be carried out in a sequence different from the sequence illustrated.

FIG. 1 is illustrative of the provision of a “bare” leadframe 12 (a Cu leadframe as provided by a leadframe supplier, usually as a tape or reel) and including at least one die pad 12A with an array of electrically conductive leads 12B around the die pad 12A.

As discussed, mounting a single chip or die 16 on the leadframe (substrate) 12 will be considered herein for simplicity. In various embodiments, plural chips or dice 16 can be mounted on the leadframe 12.

Also, the topology of the leadframe 12 illustrated herein is merely exemplary: the embodiments are in fact largely “transparent” to the leadframe configuration.

FIG. 2 is illustrative of the leadframe 12 of FIG. 1 being subjected to a non-etched adhesion promoter (NEAP) treatment performed over the whole surface of the leadframe 12. The resulting NEAP layer (e.g., copper plus silver oxide) is designated 1200. In one embodiment, the NEAP layer 1200 is a continuous layer that covers at least the entire or all of the upper surface of the leadframe 12.

It is noted that various leadframe suppliers have the capability of supplying leadframe material 12 that has been already subjected to NEAP processing and thus already include a NEAP layer 1200 as supplied from the supplier.

According to one embodiment, a plating process, comprising at least one silver plating can be applied to the leadframe prior to the NEAP treatment. Alternatively, a silver-plated leadframe (with no Cu layer underneath) can be used, as provided by a leadframe supplier.

FIG. 3 is illustrative of certain areas of the leadframe 12 such as the die pad 12A plus (at least one) second electrical die pad or contact land 12A′ being identified as areas from which the NEAP layer formed in the step of FIG. 2 is intended to be (selectively) removed.

This is in order to re-expose the underlying metal (e.g., copper, silver or various alloys) of the leadframe 12.

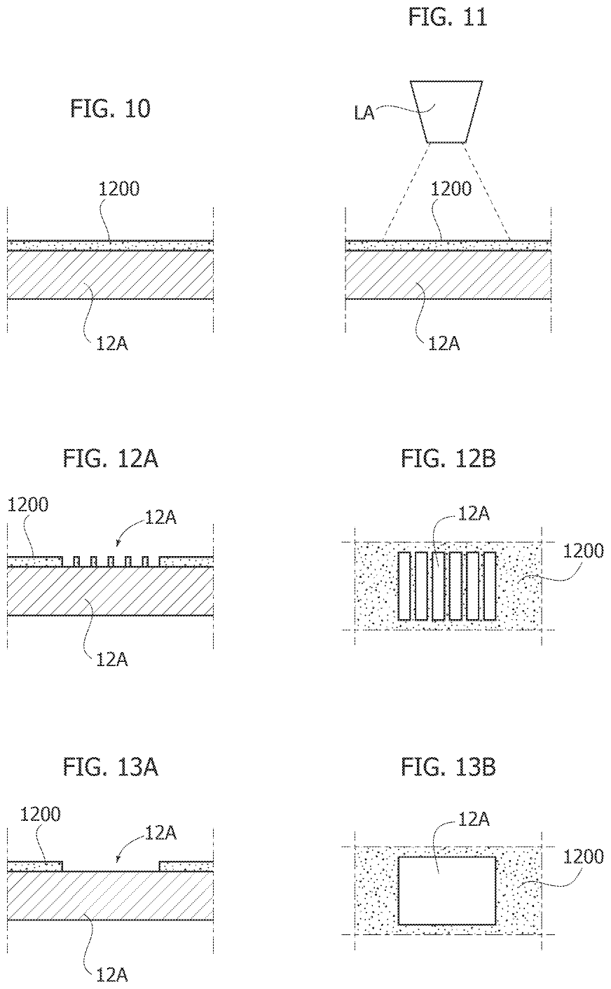

FIG. 4 is illustrative of laser beam energy being applied to the leadframe 12 (see also FIGS. 10, 11, 12A, 12B, 13A and 13B, in the respect) in order to selectively remove the NEAP layer 1200 at the die pads 12A and 12A′. In that way the underlying metal (e.g., copper, silver or various alloys) of the leadframe 12 that was lined by the NEAP layer 1200 is re-exposed (that is, uncovered). In one embodiment, the entire upper surface of the leadframe 12 is cover by the NEAP layer 1200 except for the portions selectively removed.

As illustrated in the cross-sectional view of FIG. 5—where a portion of the die pad 12A is visible—laser ablation can be advantageously implemented in such a way to involve, in addition to removal of the NEAP layer 1200, also a contained removal of the metal material (e.g., copper, silver or various alloys) of the leadframe 12. Stated differently, portions of an upper surface of the lead frame 12 may be removed such that recesses are formed in the upper surface of the lead frame 12. For example, as best shown in FIG. 5, a recess is formed for the die pad 12A. This facilitates checking that complete ablation of the NEAP layer has been successfully completed.

FIGS. 6 and 7 are illustrative of solder material 120 (including, e.g., high thermal and electrical conductivity solder paste) being dispensed at those areas of the leadframe, e.g., the die pads 12A and 12A′, that have been re-exposed in response to the (selective) laser ablation of the NEAP layer.

As illustrated in the cross-sectional view of FIG. 7—where a portion of the die pad 12A is again visible—the solder material 120 fills the recessed zones (e.g., the recesses discussed with respect to FIGS. 4 and 5) of the leadframe 12 that have been re-exposed in response to the (partial) laser ablation of the NEAP layer 1200.

As likewise visible in the cross-sectional view of FIG. 7, solder material 120 can be advantageously dispensed in such a way that the solder material 120 “overfills” the recessed zones of the leadframe that have been re-exposed in response to the (partial) laser ablation of the NEAP layer. For example, the solder material 120 is dispensed such that the solder material 120 extends past the upper surface of the leadframe 12 and contacts the NEAP layer 1200.

In that way, the solder material 120 will (marginally) overflow with respect to the substrate 12: that is, the solder material 120 will have an upper or external surface somewhat protruding or emerging with respect to the surface of the adjacent regions of the leadframe 12.

It will be otherwise appreciated that the “unablated” NEAP layer forms (e.g., around the die pads 12A, 12A′) a sort of peripheral containment rim (or “dyke”) that effectively counters undesired spilling (splashing) of the solder material 120—in a flowable state—sidewise of the die pads 12A and 12A′ that have been re-exposed via laser ablation.

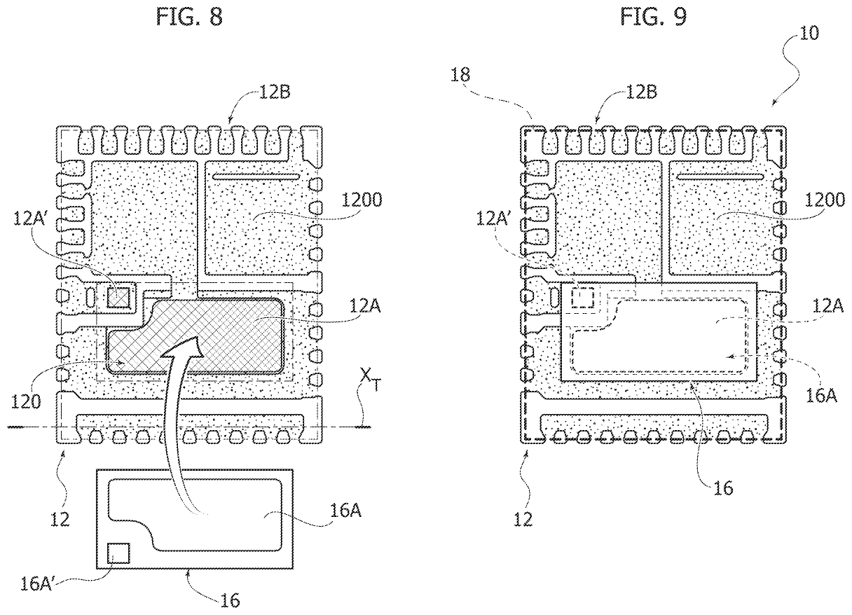

The sequence of FIGS. 8 and 9 is exemplary of a chip of die 16 being overturned (“flipped”) onto the die pads 12A, 12A′ for attachment onto the leadframe 12.

As represented in FIG. 8, the die 16 is provided at its surface intended to face the substrate or leadframe 12 with attachment regions 16A, 16A′ whose geometry matches (in a complementary manner) the geometry (e.g., position and, possibly, shape) of the die pads 12A and 12A′.

That is:
the attachment region 16A has a geometry that matches (in a complementary, mirror-like manner) the geometry of the die pad 12A, and
the attachment region 16A′ has a geometry that matches (in a complementary, mirror-like manner) the geometry of the die pad 12A′.

As exemplified in FIG. 8, flipping the chip or die 16 onto the leadframe 12 can be regarded as taking place “book-like” around a (notional) tilting axis X_{T} so that, once flipped/tilted, the chip or die 16 is superposed on the leadframe 12 with:
the attachment region 16A of the chip or die 16 superposed on the die pad 12A, and
the attachment region 16A′ of the chip or die 16 superposed on the die pad 12A′.

Once the lead or chip 16 flipped onto the leadframe 12 (on top of solder material 120), the masses of solder material 120 dispensed at the die pads 12A and 12A′ will be sandwiched, respectively:
between the die pad 12A and the attachment region 16A of the chip or die 16, and
between the die pad 12A′ and the attachment region 16A′ of the chip or die 16.

By way of example, letting the die pads 12A and 12A′ and the attachment regions 16A, 16A′ have complementary geometries can be simply obtained by ablating the die pads 12A and 12A′ at positions and with shapes that are mirror-images of the positions and shapes of attachment regions 16A, 16A′ (with respect to the notional tilting axis X_{T}).

In the examples illustrated herein, the first die area 16A extends over a major portion (e.g., 80%-90%) of the die attachment surface of the semiconductor die 16. This facilitates effective removal of heat produced by the chip 12 during operation.

The second die area (16A′) extends over a minor portion (20%-10%) of the die attachment surface of the at least one semiconductor die 16, optionally at a corner of the die or chip 16.

Once the lead or chip 16 flipped onto the leadframe 12 (with the solder paste 120 solidified, e.g., via thermal or UV curing) the resulting assembly can be submitted to reflow and other processing steps (e.g., molding the encapsulation compound 18, singulation, and so on) to complete the device 10.

The sequence of FIGS. 1 to 9 is thus exemplary of attaching at least one semiconductor die 16 onto a die mounting surface of a substrate 12 having a non-etched adhesion promoter, NEAP layer 1200 over the die mounting surface.

As illustrated, the semiconductor die 16 has an attachment surface comprising at least one first die area 16A and one second die area 16A′.

These areas 16A, and 16A′ are wettable by electrically conductive solder material 120, with the first die area 16A and second die area 16A′ otherwise mutually electrically isolated.

Selectively removing (e.g., via laser ablation as exemplified by the reference LA in FIG. 1) the NEAP layer 1200 from the first 12A and second 12A′ substrate areas of the die mounting surface of the substrate occurs in such a way that the first substrate area 12A and the second substrate area 12A′ have complementary shapes with respect to the first die area 16A the second die area 16B′ of the semiconductor die 16, respectively,

In that way, the NEAP-ablated areas 12A, 12A′ can be used as a solder mask for solder material (e.g., hybrid glue) 120 to define die-to-leadframe connection areas for a flip-chip, e.g., power die. The NEAP-ablated areas 12A, 12A′ match the die wettable areas 16, 16A′ when the die 16 is flipped.

This provides (at least) two electrical connections to the die 16.

For instance, this may be a field-effect power transistor, with drain and gate terminals connected to the die pad 12A, 12A′ and the source connection provided, e.g., via a clip.

As visible, e.g., at the bottom of FIG. 8, the first die area 16A may thus extend over a major portion of the die attachment surface of the semiconductor die 16 while the second die area 16A′ extends over a minor portion of the die attachment surface, optionally at a corner thereof.

A device package and manufacturing method are thus provided where selective removal of a NEAP layer at two mutually electrically isolated die pad regions (12A and 12A′) provides two “mask” reasons for dispensing die attach material such as the paste 120 at the solder mask regions 12A, 12A′ thus facilitating flip-chip mounting of a die 16 with wettable regions 16 and 16A′ matching the regions 12A, 12A′ laser-ablated in the NEAP layer 1200.

FIG. 11 is a deliberately simplified representation of laser beam energy LA being applied to the leadframe 12 to selective remove the NEAP layer 1200 at the die pad 12A (this applies identically to the die pad 12A′) to re-expose the underlying metal (e.g., copper, silver or various alloys) of the leadframe 12 that was previously lined by the NEAP layer

As exemplified, laser ablation can be customized in a variety of ways ranging from partial laser ablation (e.g., stripe-like, via laser beam raster scan as exemplified in FIGS. 12A and 12B) to total laser ablation (e.g., as exemplified in FIGS. 13A and 13B) of the area such as the die pad 12A from which the NEAP layer 1200 is desired to be removed. For example, in FIGS. 12A and 12B, a plurality of parallel rectangular portions of the NEAP layer 1200 are removed to form a striped like pattern in the NEAP layer 1200. The plurality of parallel rectangular portions are separated from each other by portions of the NEAP layer 1200. In FIGS. 13A and 13B, a single rectangular portion of the NEAP layer 1200 is removed.

The various ways for selective laser ablation of thin NEAP oxide layer 1200 illustrated herein facilitate re-exposing selected pad surfaces (e.g., 12A, 12A′) that can precisely match the “wettable” connection areas 16A, 16A′ in the chip or die 16.

Selective laser ablation of the NEAP layer facilitates letting the geometry of the ablated areas (e.g., 12A, 12A′) fully and accurately match the geometry of the “wettable” areas 16A, 16A′ of the semiconductor ship or die.

Also, areas exposed in the leadframe material (e.g., metals) are compatible with solder paste such as the solder paste 120.

Additionally, the ablated areas 12A, 12A′ being somewhat “engraved” effectively counters undesired solder paste “splashing” in response to “flip-chip” mounting of the chip 16, and/or during reflow.

Without prejudice to the underlying principles, the details and embodiments may vary, even significantly, with respect to what has been described by way of example without departing from the scope of protection.

A method, may be summarized as including attaching at least one semiconductor die (16) onto a die mounting surface of a substrate (12) having a non-etched adhesion promoter, NEAP layer (1200) over the die mounting surface, wherein the at least one semiconductor die (16) has an attachment surface including at least one first die area (16A) and one second die area (16A′), the first (16A) and second (16A′) die areas wettable by electrically conductive solder material (120), the first (16A) and second (16A′) die areas mutually electrically isolated, wherein the method includes selectively removing (LA) the NEAP layer (1200) from at least one first substrate area (12A) and one second substrate area (12A′) of the die mounting surface of the substrate (12), wherein the first substrate area (12A) and the second substrate area (12A′) of the substrate (12) have complementary shapes with respect to the first (16A) die area and the second (16A′) die area of the semiconductor die (16), respectively, dispensing electrically conductive solder material (120) on the first substrate area (12A) and the second substrate area (12A′) of the substrate (12), and flipping the at least one semiconductor die (16) onto the die (16) mounting substrate (12) with the first die area (16A) and the second die area (16A′) aligned with the first substrate area (12A) and the second substrate area (12A′) of the substrate (12) having the solder material (120) dispensed thereon, wherein the electrically conductive solder material (120) provides electrical coupling of the first die area (16A) and the first substrate area (12A), and the second die area (16A′) and the second substrate area (12A′).

Selectively removing (LA) the NEAP layer (1200) may include laser ablating (LA) the NEAP layer (1200) at said at least one first substrate area (12A) and one second substrate area (12A′) of the die mounting surface of the substrate (12).

Selectively removing (LA) the NEAP layer (1200) may include removing the NEAP layer (1200) over the entirety of said at least one first substrate area (12A) and one second substrate area (12A′) of the die mounting surface of the substrate (12), or removing the NEAP layer (1200) over a portion of said at least one first substrate area (12A) and one second substrate area (12A′) of the die mounting surface of the substrate (12).

Selectively removing (LA) the NEAP layer (1200) may include removing the NEAP layer (1200) over a portion of said at least one first substrate area (12A) and one second substrate area (12A′) of the die mounting surface of the substrate (12), wherein said removing follows a striped pattern.

Selectively removing (LA) the NEAP layer (1200) may include ablating (LA) material of the substrate (12) underlying the NEAP layer (1200) at said at least one first substrate area (12A) and one second substrate area (12A′) of the die mounting surface of the substrate (12).

The method may include dispensing electrically conductive solder material (120) by overfilling said at least one first substrate area (12A) and one second substrate area (12A′) of the die mounting surface of the substrate (12).

A device (10), may be summarized as including at least one semiconductor die (16) attached onto a die mounting surface of a substrate (12) having a non-etched adhesion promoter, NEAP layer (1200) over the die mounting surface, wherein the at least one semiconductor die (16) has an attachment surface including at least one first die area (16A) and one second die area (16A′), the first (16A) and second (16A′) die areas having electrically conductive solder material (120) thereon, the first (16A) and second (16A′) die areas mutually electrically isolated, wherein at least one first substrate area (12A) and one second substrate area (12A′) of the die mounting surface of the substrate (12) have the NEAP layer (1200) removed therefrom, wherein the first substrate area (12A) and the second substrate area (12A′) of the substrate (12) have complementary shapes with respect to the first (16A) die area and the second (16A′) die area of the semiconductor die (16), respectively, the at least one semiconductor die (16) flip-mounted onto the die (16) mounting substrate (12) with the first die area (16A) and the second die area (16A′) aligned with the first substrate area (12A) and the second substrate area (12A′) of the substrate (12) having the solder material (120) dispensed thereon, wherein the electrically conductive solder material (120) provides electrical coupling of the first die area (16A) and the first substrate area (12A), and the second die area (16A′) and the second substrate area (12A′).

The at least one first substrate area (12A) and one second substrate area (12A′) of the die mounting surface of the substrate (12) may have the NEAP layer (1200) removed therefrom over the entirety of said at least one first substrate area (12A) and one second substrate area (12A′), or over a, preferably stripe-like, portion of said at least one first substrate area (12A) and one second substrate area (12A′).

Material of the substrate (12) may be ablated (LA) from at said at least one first substrate area (12A) and one second substrate area (12A′) of the die mounting surface of the substrate (12).

The at least one first die area (16A) may extend over a major portion of the die attachment surface of the at least one semiconductor die (16) and the at least one second die area (16A′) may extend over a minor portion of the die attachment surface of the at least one semiconductor die (16), preferably at a corner thereof.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
attaching a semiconductor die onto a die mounting surface of a substrate, the substrate having a non-etched adhesion promoter (NEAP) layer on the die mounting surface, the semiconductor die having an attachment surface including a first die area and a second die area, the first and second die areas wettable by electrically conductive solder material, the first and second die areas being mutually electrically isolated,
wherein the method includes:
selectively removing the NEAP layer from a first substrate area and a second substrate area of the die mounting surface of the substrate, the first substrate area and the second substrate area of the substrate have complementary shapes with respect to the first die area and the second die area of the semiconductor die, respectively;
dispensing the electrically conductive solder material on the first substrate area and the second substrate area of the substrate; and
flipping the semiconductor die onto the die mounting surface with the first die area and the second die area aligned with the first substrate area and the second substrate area of the substrate, respectively, having the electrically conductive solder material dispensed thereon, the electrically conductive solder material electrically coupling:
the first die area to the first substrate area, and
the second die area to the second substrate area.

2. The method of claim 1, wherein selectively removing the NEAP layer includes laser ablating the NEAP layer at the first substrate area and the second substrate area of the die mounting surface of the substrate.

3. The method of claim 1, wherein selectively removing the NEAP layer includes:
removing the NEAP layer over the entirety of the first substrate area and the second substrate area of the die mounting surface of the substrate, or
removing the NEAP layer over a portion of the first substrate area and the second substrate area of the die mounting surface of the substrate.

4. The method of claim 1, wherein selectively removing the NEAP layer includes removing the NEAP layer over a portion of the first substrate area and the second substrate area of the die mounting surface of the substrate, the removing of the NEAP layer following a striped pattern.

5. The method of claim 1, wherein selectively removing the NEAP layer includes ablating material of the substrate underlying the NEAP layer at the first substrate area and the second substrate area of the die mounting surface of the substrate.

6. The method of claim 1, wherein dispensing electrically conductive solder material includes overfilling the first substrate area and the second substrate area of the die mounting surface of the substrate with the electrically conductive solder material.

7. A device, comprising:
a substrate including a die mounting surface, and a non-etched adhesion promoter (NEAP) layer on the die mounting surface; and
a semiconductor die attached to the die mounting surface of the substrate, the semiconductor die having an attachment surface including a first die area and a second die area, the first and second die areas having electrically conductive solder material thereon, the first and second die areas being mutually electrically isolated,
wherein:
a first substrate area and a second substrate area of the die mounting surface of the substrate have the NEAP layer removed therefrom,
the first substrate area and the second substrate area of the substrate have complementary shapes with respect to the first die area and the second die area of the semiconductor die, respectively,
the semiconductor die is flip-mounted onto the die mounting substrate with the first die area and the second die area aligned with the first substrate area and the second substrate area of the substrate, respectively, having the electrically conductive solder material dispensed thereon, and
the electrically conductive solder material electrical couples:
the first die area to the first substrate area, and
the second die area to the second substrate area.

8. The device of claim 7, wherein the first substrate area and the second substrate area of the die mounting surface of the substrate have the NEAP layer removed therefrom:
over the entirety of the first substrate area and the second substrate area, or
over a striped portion of the first substrate area and the second substrate area.

9. The device of claim 7, wherein material of the substrate is ablated from the first substrate area and the second substrate area of the die mounting surface of the substrate.

10. The device of claim 7, wherein
the first die area extends over a first portion of the attachment surface of the semiconductor die, and
the second die area extends over a second portion, which is smaller than the first portion, of the attachment surface of the semiconductor die.

11. The device of claim 10 wherein the second portion of the attachment surface of the semiconductor die is at a corner of the semiconductor die.

12. A method, comprising:
exposing a first portion of a die mounting surface of a lead frame by removing a first portion of a non-etched adhesion promoter (NEAP) layer on the die mounting surface;
dispensing attachment material on the first portion of the die mounting surface; and
attaching a semiconductor die to the lead frame by positioning the semiconductor die on the attachment material.

13. The method of claim 12, wherein the removing of the first portion of the NEAP layer includes forming a recess in the first portion of the die mounting surface.

14. The method of claim 13, wherein the dispensing of the attachment material includes filling the recess with the attachment material.

15. The method of claim 14, wherein the dispensing of the attachment material includes overfilling the recess with the attachment material such that attachment material extends past the die mounting surface.

16. The method of claim 12, further comprising:
exposing a second portion of the die mounting surface of the lead frame by removing a second portion of the NEAP layer on the die mounting surface; and
dispensing the attachment material on the second portion of the die mounting surface.

17. The method of claim 12 wherein the NEAP layer is a continuous layer that covers the die mounting surface.

18. The method of claim 12 wherein the removing of the first portion of the NEAP layer includes removing a plurality of rectangular portions of the NEAP layer.

19. The method of claim 12 wherein the attachment material is electrically conductive, and electrically couples the lead frame to the semiconductor die.

20. The method of claim 12 the NEAP layer includes an oxide layer.
